(19) United States
(12) Patent Application Publication
(10) Pub. No.: US 2023/0343658 A1
(43) Pub. Date: Oct. 26, 2023

(54) TEST CIRCUITRY STRUCTURE

(71) Applicant: NANYA TECHNOLOGY CORPORATION, New Taipei City (TW)

(72) Inventor: Cheng-Hsien Hsieh, New Taipei City (TW)

(73) Assignee: NANYA TECHNOLOGY CORPORATION, New Taipei City (TW)

(21) Appl. No.: 17/725,526

(22) Filed: Apr. 20, 2022

(51) Int. Cl. H01L 21/66

(52) U.S. Cl. CPC H01L 22/34

(57) ABSTRACT

A test circuitry structure includes a first pad, a second pad, a plurality of tested devices, and a plurality of switches. Each of the switches is coupled to each of the tested devices in series between the first pad and second pad. The switches are respectively triggered by a plurality of control signals to be turned on.

### BACKGROUND OF THE INVENTION

### Technical Field

The present invention generally relates to a test circuitry structure, and more particularly to the test circuitry structure which is embedded in a wafer.

### Description of Related Art

In a semiconductor wafer, test circuit structures (test keys) are used to test process dependent rules or device related characteristics of the wafer. The test keys are usually disposed on scribe line areas of the wafer. For electrical connect to each of the test key, pads corresponding to each of the test keys are necessary. However, an area size of the pad is quite larger than a size of a tested circuit in the test key. In order to dispose more tested circuit, the area size of the pad need to be reduced.

But, for the tested circuit for electrostatic discharge (ESD) protection or latch-up protection, even reduce the size of the pad is not enough since switch or addressable structure of the test key can't sustain high voltage and/or current during a testing operation of the test key.

### SUMMARY OF THE INVENTION

The present invention provides a test circuitry structure including a plurality of tested circuit, and each of the tested circuit is configured for an electrostatic discharge protection or a latch-up protection.

The test circuitry structure is disposed on a wafer. The test circuitry structure includes a first pad, a second pad, a plurality of tested devices, and a plurality of switches. Each of the switches is coupled to each of the tested devices in series between the first pad and second pad. The switches are respectively triggered by a plurality of control signals to be turned on.

Accordingly, present disclosure provides the test circuitry structure which can selects one of the tested devices to be tested by triggering corresponding switch. Such as that, the test circuitry structure can be addressable and provides more tested devices by sharing same pads.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a block diagram of a test circuitry structure according to an embodiment of present disclosure.

FIG. 2 illustrates a block diagram of a test circuitry structure according to another embodiment of present disclosure.

FIG. 3 illustrates a structure diagram of a switch of a test circuitry structure according to an embodiment of present disclosure.

FIG. 4 illustrates a structure diagram of a switch of a test circuitry structure according to another embodiment of present disclosure.

FIG. 5 illustrates a structure diagram of a tested device of a test circuitry structure according to an embodiment of present disclosure.

### DESCRIPTION OF THE EMBODIMENTS

Reference will now be made in detail to the present preferred embodiment of the invention, examples of which are illustrated in the accompanying drawings. Wherever possible, the same reference numbers are used in the drawings and the description to refer to the same or like parts.

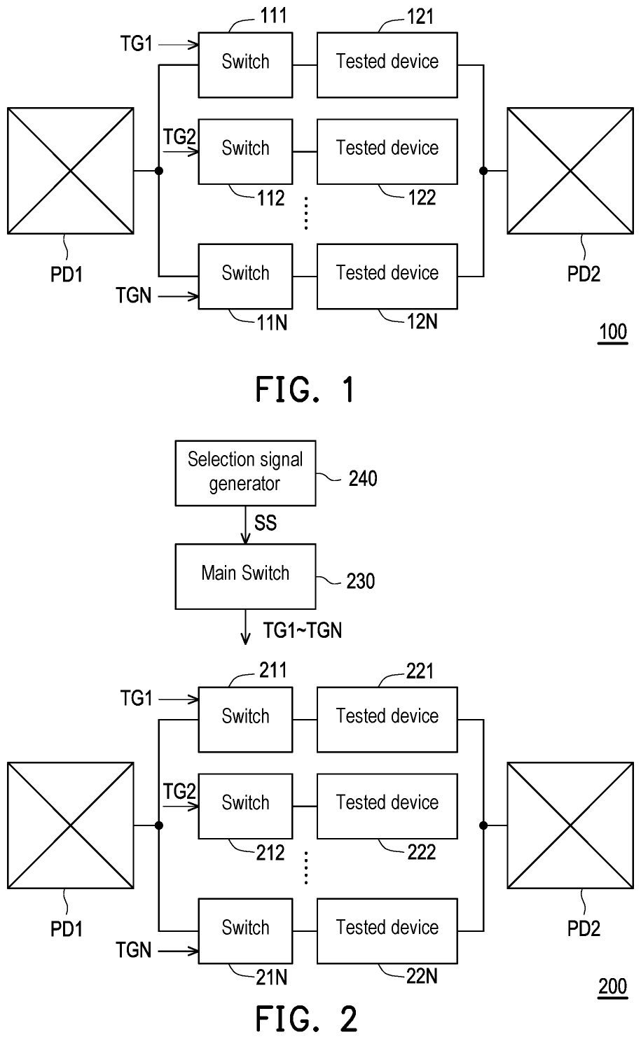

Please refer to FIG. 1, which illustrates a block diagram of a test circuitry structure according to an embodiment of present disclosure. The test circuitry structure 100 includes a first pad PD1, a second pad PD2, a plurality of switches 111˜11N and a plurality of tested device 121˜12N. In this embodiment, each of the switches 111˜11N is coupled to each of the tested devices 121˜12N in series between the first pad PD1 and second pad PD2. The switches 111˜11N are respectively triggered by a plurality of control signals TG1˜TGN to be turned on. In a test operation, take the tested device 121 is selected as an example, the corresponding switch 111 can be turned on according to the control signal TG1. Such as that, the first pad PD1, the switch 111, the tested device 121 and the second pad PD2 are coupled in series. Testing signal can be transmitted to the tested device 121 through the first pad PD1 and/or the second pad PD2 and testing result can be obtained from the tested device 121 through the first pad PD1 and/or the second pad PD2. In another test operation, another switch (such as the switch 112) can be turned on, and the corresponding tested device 122 can be coupled to the first pad PD1 and the second pad PD2 for performing the test operation.

Each of the switches 111˜11N may be turned on according to each of the control signals TG1˜TGN, and each of the tested device 121˜12N can be tested in sequential. It should be noted here, merely one of the plurality of switches 111˜11N is turned on at a single testing time period to be couple one of the tested devices 121˜12N to the first pad PD1 and the second pad PD2.

In this embodiment, each of the switches 111˜11N may be a silicon-controlled rectifier (SCR) or a gated diode. Each of the tested devices 121˜12N may be an electrostatic discharge (ESD) protection circuit or a latch-up protection circuit. That is, each of the switches 111˜11N may provide a low turned-on resistance which is lower than a reference value; each of the switches 111˜11N may have a high voltage endurance which is higher than a threshold voltage; and each of the switches 111˜11N may have a high current endurance which is higher than a threshold current. The reference value, the threshold voltage and the threshold current may be set by a designer, and no specific limitation here.

That is, each of the switches 111˜11N has low turned-on resistance and high voltage and/or current endurance, and such as that ESD and/or latch-up test on each of the test devices 121˜12N can be performed efficiency.

On the other hand, an area of the first pad PD1 and an area the second pad PD2 may be same, and the area of the first pad PD1 may be larger than an area of each of the tested devices 121˜12N. Such as that, the tested devices 121˜12N, the switches 111˜11N the first pad PD1 and the second pad PD2 can form a test key and be disposed in a scribe line of the wafer. A plurality of functions can be tested by a single test key.

Please refer to FIG. 2, which illustrates a block diagram of a test circuitry structure according to another embodiment of present disclosure. The test circuitry structure 200 includes a first pad PD1, a second pad PD2, a plurality of switches 211˜21N, a plurality of tested device 221˜22N, a main switch 230 and a selection signal generator 240. In this embodiment, each of the switches 111˜11N is coupled to each of the tested devices 121˜12N in series between the first pad PD1 and second pad PD2. The switches 111˜11N are respectively triggered by a plurality of control signals TG1˜TGN to be turned on. The main switch 230 is coupled to the switches 211˜21N. The main switch 230 is used to generate the control signals TG1˜TGN according to a selection signal SS. The selection signal generator 240 is coupled to the main switch 230, and is configured to generate the selection signal SS.

In this embodiment, in a test sequence, the selection signal generator 240 may generate the selection signal SS, and the main switch 230 may generate the control signals TG1˜TGN according to a selection signal SS to turn on one of the switches 211˜21N. In one embodiment, one of the tested devices 221˜22N, take the tested device 221 as an example, can be selected for testing. The selection signal generator 240 may generate the selection signal SS and the main switch 230 can activate the control signal TG1 to turn on the switch 211, and the tested device 221 can be tested. That is, any one of the tested devices 221˜22N can be addressed through the selection signal SS, and the test circuitry structure 200 may be an addressable test circuitry structure.

In another embodiment, the selection signal generator 240 may generate the selection signal SS according to a testing sequence, and the main switch 230 may activate each of the control signals TG1˜TGN according to the testing sequence. Such as that, each of the tested device 221 can be tested according to the testing sequence. In this embodiment, the testing sequence can be set internally or randomly, and no special limitation here.

In this embodiment, the selection signal generator 240 may be a logic circuitry. In some embodiments, the selection signal generator 240 may include a command decoder for receiving an external command and generating the selection signal SS to address the selected tested device. In some embodiments, the selection signal generator 240 may include a counter to generate the selection signal SS by a counting operation, and the tested devices 221˜22N may be selected in a preset sequence. Or, in some embodiments, the selection signal generator 240 may include a random number generator to generate the selection signal SS randomly, and the tested devices 221˜22N may be selected in a random sequence.

In this embodiment, the main switch 230 may be implemented by a de-multiplexer. The main switch 230 may receive a base signal with an activated voltage value, and transmits the base signal to trigger one of the control signals TG1˜TGN according to the selection signal SS. A hardware structure of the de-multiplexer is well known by a person skilled in this art, and no more description here.

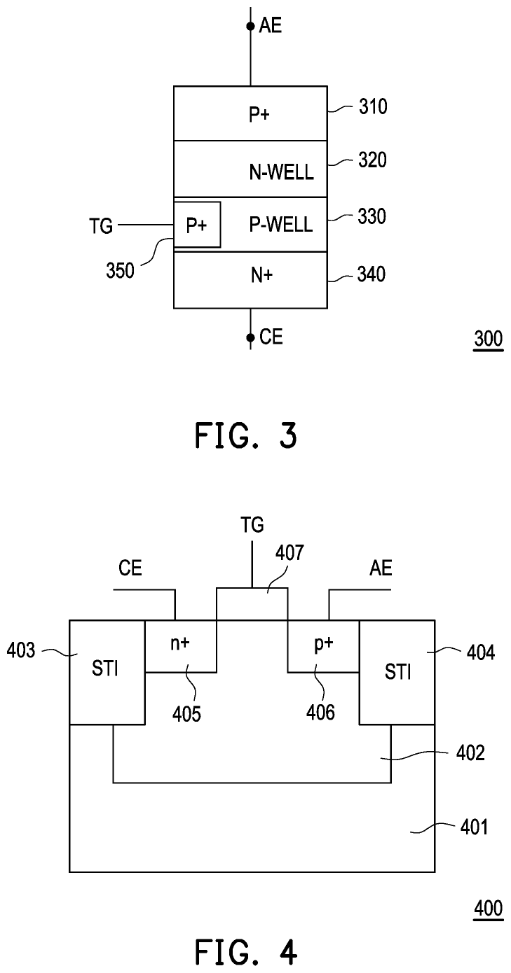

Please refer to FIG. 3, which illustrates a structure diagram of a switch of a test circuitry structure according to an embodiment of present disclosure. In this embodiment, the switch 300 of the test circuitry structure may be a silicon-controlled rectifier. The switch 300 includes P-type heavily doped regions (P+) 310 and 350, a N-type well (N-WELL) 320, a P-type well (P-WELL) 330 and a N-type heavily doped regions (N+) 340. The P-type heavily doped region (P+) 310, a N-type well (N-WELL) 320, a P-type well (P-WELL) 330 and a N-type heavily doped regions (N+) 340 are overlapped in sequence. The P-type heavily doped region (P+) 310 forms an anode end AE of the switch 300, and the N-type heavily doped regions (N+) 340 forms a cathode end CE of the switch 300. The P-type heavily doped region (P+) 350 is disposed in the P-type well (P-WELL) 330 to form a control end. In this embodiment, the anode end AE of the switch 300 may be coupled to a first pad, the cathode end CE of the switch 300 may be coupled to a corresponding tested device, and the P-type heavily doped region (P+) 350 may receive a corresponding control signal TG.

It should be noted here, the structure of the switch 300 in FIG. 3 is only a schematic diagram for a SCR which can be implemented in the test circuitry structure of present disclosure. In fact, any structure of a SCR well known by a person skilled in this art can be implanted in the test circuitry structure of present disclosure, too. The structure of the switch 300 in FIG. 3 does not limit an invention scope of present disclosure.

Please refer to FIG. 4, which illustrates a structure diagram of a switch of a test circuitry structure according to another embodiment of present disclosure. In this embodiment, the switch 400 of the test circuitry structure may be a gated control diode. The switch 400 includes a substrate 401, a well 402, shallow trench isolations (STI) 403 and 404, a N-type heavily doped region (N+) 405, a P-type heavily doped region (P+) 406 and a gate structure 407. In FIG. 4, the well 402 is formed in the substrate 401. The shallow trench isolations (STI) 403 and 404 are formed between the substrate 401 and the well 402, and located in two sides of the well 402. The N-type heavily doped region (N+) 405 and the P-type heavily doped region (P+) 406 are formed in the well 405, where the N-type heavily doped region (N+) 405 forms a cathode end CE of the switch 400, and the P-type heavily doped region (P+) 406 forms an anode end AE of the switch 400. The gate structure 407 is disposed over the N-type heavily doped region (N+) 405 and the P-type heavily doped region (P+) 406 and covers the well 402. The gate structure 407 forms a control end of the switch 400 for receiving a control signal TG.

It should be noted here, the structure of the switch 400 in FIG. 4 is only a schematic diagram for a gated diode which can be implemented in the test circuitry structure of present disclosure. In fact, any structure of a gated diode well known by a person skilled in this art can be implanted in the test circuitry structure of present disclosure, too. The structure of the switch 400 in FIG. 4 does not limit an invention scope of present disclosure.

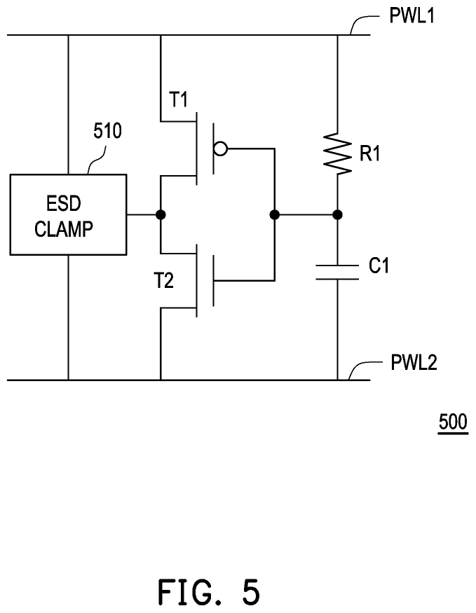

Please refer to FIG. 5, which illustrates a structure diagram of a tested device of a test circuitry structure according to an embodiment of present disclosure. The tested device 500 is an electrostatic discharge (ESD) protection circuit. The tested circuit 500 includes an ESD clamp 510, transistors T1 and T2, a resistor R1 and a capacitor C1. The resistor R1 and the capacitor C1 are coupled in series between power rails PWL1 and PWL2. The ESD clamp 510 is coupled between the power rails PWL1 and PWL2, and the transistors T1 and T2 are coupled in series between the power rails PWL1 and PWL2, too.

In this embodiment, an electrostatic discharge current on the power rail PWL1 can be dissipated through the turned-on transistors T1 and T2. The ESD clamp 510 is configured to clamp a voltage value on the power rail PWL1 of a ESD event.

Please be noted here, the transistors T1 and T2 can be implemented by any type of transistor well known by a person skilled in this art. In special, each of the transistors T1 and T2 may be a laterally diffused metal oxide semiconductor (LDMOS) transistor.

It should be noted here, the structure of the tested device 500 in FIG. 5 is only a schematic diagram for an ESD protection circuit which can be implemented in the test circuitry structure of present disclosure. In fact, any structure of an ESD protection circuit well known by a person skilled in this art can be implanted in the test circuitry structure of present disclosure, too. The structure of the ESD protection circuit 500 in FIG. 5 does not limit an invention scope of present disclosure.

If the tested device is a latch-up protection circuit, the latch-up protection circuit may be implemented by adding a layer of insulating oxide (called a trench) that surrounds all of N-type and P-type transistors in the tested device. The trench is configured to break parasitic silicon-controlled rectifier structure between these transistors. Of course, any structure of a latch-up protection circuit well known by a person skilled in this art can be implanted in the test circuitry structure of present disclosure.

In summary, the test circuitry structure includes a plurality of tested devices sharing same pads, and each of the tested devices can be selected by tuning on corresponding switches. Such as that, a plurality of tested devices can be disposed between two pads, and efficiency of the test circuitry structure can be increased. Furthermore, each of the tested devices can be addressed for performing testing operation in present disclosure, efficiency of the test circuitry structure can be further increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A test circuitry structure, disposed on a wafer, comprising:
a first pad;
a second pad;
a plurality of tested devices; and
a plurality of switches, wherein each of the switches is coupled to each of the tested devices in series between the first pad and second pad, the switches are respectively triggered by a plurality of control signals to be turned on.

2. The test circuitry structure according to claim 1, wherein each of the plurality of switches is a silicon-controlled rectifier or a gated diode.

3. The test circuitry structure according to claim 1, wherein each of the tested devices is an electrostatic discharge protection circuit or a latch-up protection circuit.

4. The test circuitry structure according to claim 1, further comprising:
a main switch, coupled to the plurality of switches, providing each of the plurality of control signals to each of the plurality of switches according to a selection signal.

5. The test circuitry structure according to claim 4, further comprises:
a selection signal generator, coupled to the main switch for providing the selection signal.

6. The test circuitry structure according to claim 1, wherein each of the plurality of switches provides a turned-on resistance lower than a reference value.

7. The test circuitry structure according to claim 1, wherein each of the plurality of switches has a voltage endurance higher than a threshold voltage.

8. The test circuitry structure according to claim 1, wherein each of the plurality of switches has a current endurance higher than a threshold current.

9. The test circuitry structure according to claim 1, wherein merely one of the plurality of switches is turned on at a single testing time period to couple one of the tested devices to the first pad and the second pad.

10. The test circuitry structure according to claim 1, wherein the test circuitry structure is disposed in a scribe line of the wafer.

11. The test circuitry structure according to claim 1, wherein an area of the first pad is larger than an area of each of the plurality of tested devices.
